(19) United States
(12) Patent Application Publication
(10) Pub. No.: US 2023/0175130 A1
(43) Pub. Date: Jun. 8, 2023

(54) APPARATUS FOR COATING POWDER

(71) Applicant: INDUSTRY-UNIVERSITY COOPERATION FOUNDATION HANYANG UNIVERSITY ERICA CAMPUS, Ansan-si (KR)

(72) Inventor: Taejoo PARK, Ansan-si (KR)

(73) Assignee: INDUSTRY-UNIVERSITY COOPERATION FOUNDATION HANYANG UNIVERSITY ERICA CAMPUS, Ansan-si (KR)

(21) Appl. No.: 18/061,707

(22) Filed: Dec. 5, 2022

(30) Foreign Application Priority Data
Dec. 6, 2021 (KR) 10-2021-0173142
Feb. 4, 2022 (KR) 10-2022-0014930

(51) Int. Cl. C23C 16/455

(52) U.S. Cl. CPC C23C 16/45544

(57) ABSTRACT

A powder coating apparatus includes: a reactor configured to rotate and improve reactivity of powder accommodated therein; a rotating unit including a roller positioned at a lower portion of the reactor and configured to rotate while in direct contact with the reactor and cause the reactor to rotate; and a chamber unit configured to at least partially accommodate the reactor and the rotating unit and create a predetermined environment for a deposition reaction of the powder inside the reactor. The chamber unit includes an openable/closable lid to allow the reactor to be replaced with a new reactor. Since a fastening portion is not present in the powder coating apparatus itself, full automation in which a mass production reactor is separated from the chamber unit and transferred to a holder by a robot arm is facilitated. Thus, time until a subsequent process is reduced, and product yield can be increased.

### CROSS-REFERENCE TO RELATED APPLICATION

This application claims priorities to and benefits of Korean Patent Application No. 10-2021-0173142, filed on Dec. 6, 2021, and Korean Patent Application No. 10-2022-0014930, filed on Feb. 4, 2022, the disclosure of each of which is incorporated herein by reference in its entirety.

### BACKGROUND

### 1. Field of the Invention

The present disclosure relates to an apparatus for coating powder, and more particularly, to a powder coating apparatus for a thin film deposition process using a rotation method.

### 2. Discussion of Related Art

With the expansion of the powder-related market, various methods for forming a high-quality thin film on a large amount of powder have been used.

For example, due to being able to improve electrochemical and mechanical characteristics of batteries, powder coated with a thin film is used for active materials of positive and negative electrodes, a chemical mechanical polishing (CMP) slurry, and the like and is spotlighted as a technology that can lead the state-of-the-art semiconductor/battery market.

In order to coat a nano-level thin film, a Chemical Vapor Deposition (CVD) process, an Atomic Layer Deposition (ALD) process, and the like may be applied. Among the processes, a Powder-Atomic Layer Deposition (P-ALD) method is a method in which powder (base material) is charged in a rotating reactor so that a thin film is evenly deposited on a surface of the powder (base material).

However, the conventional thin film deposition process using a rotation method has various problems. Regarding the existing reactor, due to a small internal volume, the amount of powder that can be charged per one process is relatively small, and thus the actual yield required for mass production is low. Also, since a reactor shaft and a chamber have to be manually fastened every time the process is performed, a problem occurs in that the reliability of accurate powder recovery for each position decreases due to issues such as the reactor tilting due to vibration.

The inventor of the present disclosure has finally completed the present disclosure after a long period of research and trial-and-error to address the above problems.

### SUMMARY OF THE INVENTION

Embodiments of the present disclosure provide a reactor of a large-capacity powder coating apparatus with improved yield for mass production and improved reliability of accurate powder recovery for each position.

Meanwhile, other unmentioned objectives of the present disclosure will be additionally taken into consideration within the scope easily inferable from the following detailed description and advantageous effects thereof.

A powder coating apparatus according to an embodiment of the present disclosure includes: a reactor configured to rotate and improve reactivity of powder accommodated therein; a rotating unit including a roller which is positioned at a lower portion of the reactor and configured to rotate while in direct contact with the reactor and cause the reactor to rotate; and a chamber unit configured to at least partially accommodate the reactor and the rotating unit and create a predetermined environment for a deposition reaction of the powder inside the reactor, wherein the chamber unit includes an openable/closable lid to allow the reactor to be replaced with a new reactor.

The chamber unit may further include a sliding driving module configured to slide the lid from a closing position to an opening position.

The sliding driving module may include a moving block configured to move along a transfer line extending in one direction and a cylinder provided on the moving block and configured to push the lid upward and open the lid.

The moving block may include a plurality of blocks placed on the transfer line, a body configured to provide a space for mounting the plurality of blocks, and an auxiliary guide coupled to the body to aid in alignment while sliding occurs.

The chamber unit may further include an upper heater configured to heat the reactor placed therein from above the reactor, wherein the upper heater is coupled to the lid and pushed upward along with the lid while the lid is pushed upward by the cylinder, and in a state in which the lid is at the opening position, an upper portion of the reactor may be completely exposed through an upper side of the chamber unit.

The upper heater and the lid may be coupled to each other through a fastener.

The powder coating apparatus may further include: a robot arm provided to grip the reactor; and a holder, wherein the robot arm may perform driving to grip the exposed reactor, withdraw the gripped reactor vertically upward, and mount the withdrawn reactor on the holder.

The roller may include a first roller disposed at one side of the lower portion of the reactor and a second roller disposed at the other side of the lower portion of the reactor, and the first roller and the second roller may be disposed at positions not interfering with replacement of the reactor with a new reactor.

The reactor may include a liner configured to narrow an accommodation space therein configured to accommodate the powder.

The first roller and the second roller may have a sleeve configured to form a diameter adaptive to a diameter of the reactor so that the first roller and the second roller are able to come in direct contact with the reactor regardless of the diameter of the reactor.

The first and second rollers and the reactor may have therebetween a structure in which concave and convex portions come in contact.

The chamber unit may further include: a gas supply module configured to supply a process gas to one side of the reactor; and a gas damper module configured to come in close contact with the other side of the reactor to serve as an impact absorber.

A powder coating apparatus according to an embodiment of the present disclosure includes: a reactor configured to rotate and improve reactivity of powder accommodated therein; a rotating unit positioned at a lower portion of the reactor and configured to rotate while in direct contact with the reactor and cause the reactor to rotate; and a chamber unit configured to at least partially accommodate the reactor and the rotating unit and create a predetermined environment for a deposition reaction of the powder inside the reactor, wherein the chamber unit may further include a lid which is provided to be slidable in a first direction and configured to cause an upper portion of the reactor disposed therein to be exposed to an outside and a robot arm which is provided to be slidable in a second direction and configured to withdraw the exposed reactor in a third direction.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a view illustrating the overall configuration of a powder coating apparatus according to an embodiment of the present disclosure;

FIG. 2 is a view for illustrating an internal configuration of a chamber unit of FIG. 1;

FIG. 3 is a view illustrating the overall configuration of the powder coating apparatus viewed from a direction different from that of FIG. 1;

FIG. 4 is a view for illustrating an internal configuration of the chamber unit of FIG. 3;

FIG. 5 is a view illustrating a vertical cross-section of the inside of the powder coating apparatus according to an embodiment of the present disclosure;

FIG. 6 is a view illustrating a state in which a lid of the chamber unit is opened by a sliding driving module according to an embodiment of the present disclosure;

FIGS. 7 and 8 are views illustrating the overall configuration of the powder coating apparatus for describing replacement of a reactor according to an embodiment of present disclosure;

FIGS. 9A to 9C are views illustrating various embodiments of the reactor according to an embodiment of the present disclosure in terms of the relationship with a roller; and

FIGS. 10A to 10C are views illustrating various embodiments of a reactor according to another embodiment of the present disclosure in terms of the relationship with the roller.

Note that the accompanying drawings are only exemplary and are provided as reference for understanding of the technical spirit of the present disclosure, and the scope of the present disclosure is not limited by the accompanying drawings.

### DETAILED DESCRIPTION OF EXEMPLARY EMBODIMENTS

Hereinafter, exemplary embodiments of the present disclosure will be described. Thicknesses and gaps shown in the drawings are only for convenience of description, and the thicknesses may be exaggerated as compared to actual physical thicknesses. In describing the present disclosure, description of a known configuration irrelevant to the gist of the present disclosure may be omitted. In assigning reference numerals to elements in each drawing, it should be noted that the same reference numerals are assigned to the same elements where possible even when the elements are illustrated in different drawings.

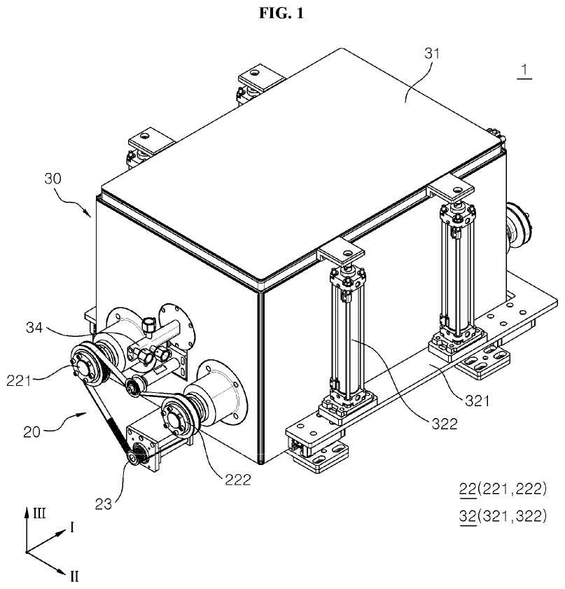

FIG. 1 is a view illustrating the overall configuration of a powder coating apparatus according to an embodiment of the present disclosure.

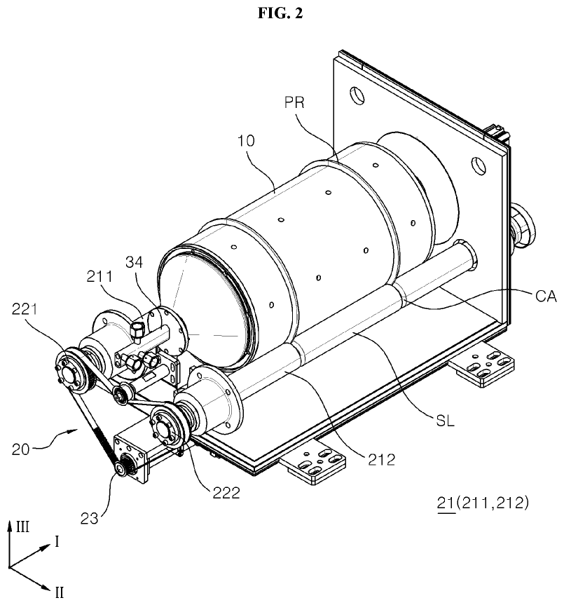

FIG. 2 is a view for illustrating an internal configuration of a chamber unit of FIG. 1.

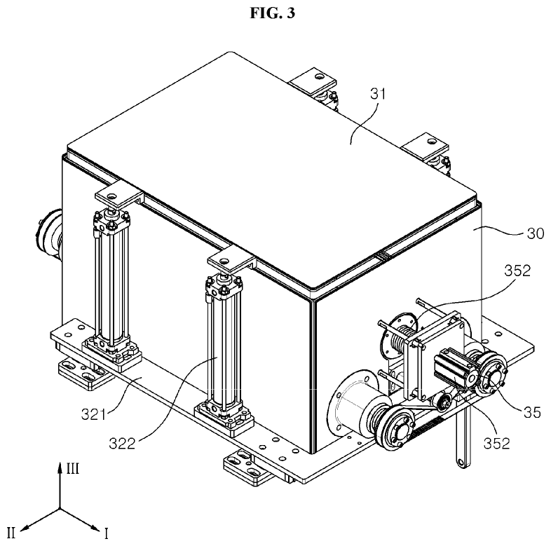

FIG. 3 is a view illustrating the overall configuration of the powder coating apparatus viewed from a direction different from that of FIG. 1.

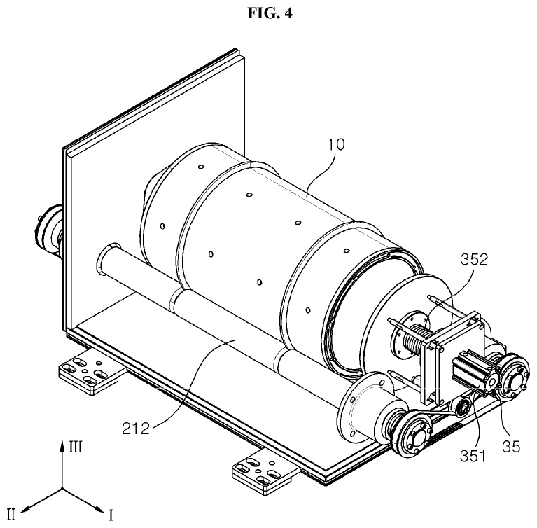

FIG. 4 is a view for illustrating an internal configuration of the chamber unit of FIG. 3.

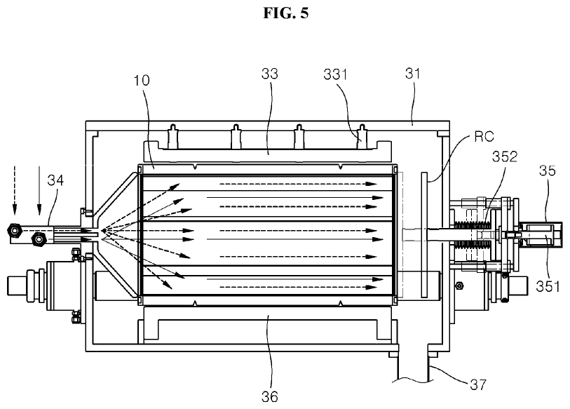

Also, FIG. 5 is a view illustrating a vertical cross-section of the inside of the powder coating apparatus according to an embodiment of the present disclosure.

First referring to FIGS. 1 and 2, a powder coating apparatus 1 includes a reactor 10, a rotating unit 20, and a chamber unit 30.

The reactor 10 rotates and improves reactivity of powder (not illustrated) accommodated therein. The powder is coated inside the reactor.

The reactor is made of a metal or metal alloy material. The material of the reactor is not limited thereto, and the reactor may also be made of a Teflon material having corrosion resistance and chemical resistance.

The rotating unit 20 includes a roller 21 configured to rotate the reactor 10. The roller 21 is positioned at a lower portion of the reactor 10 and rotates while in direct contact with the reactor to cause the reactor to rotate.

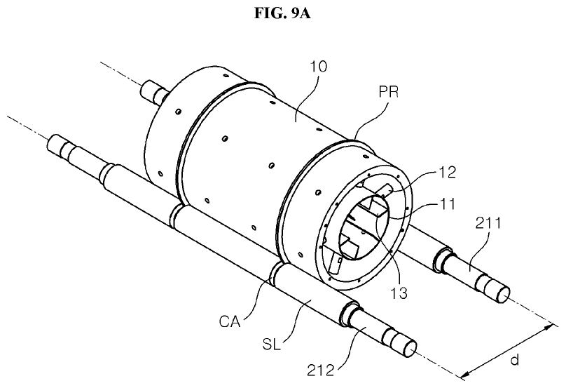

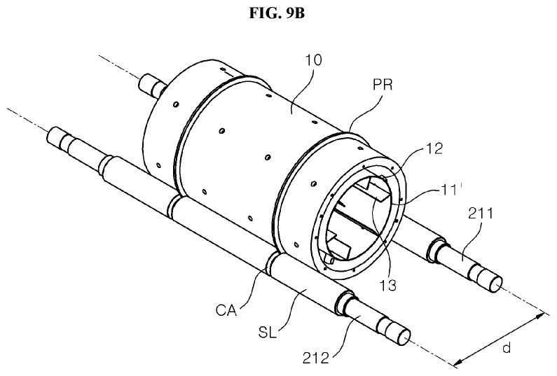

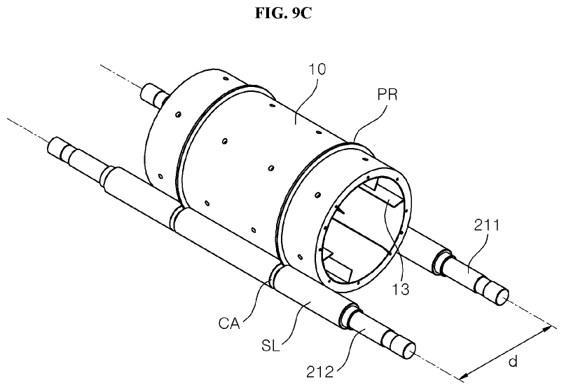

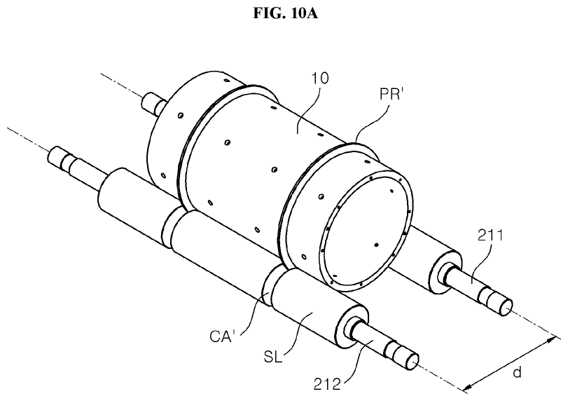

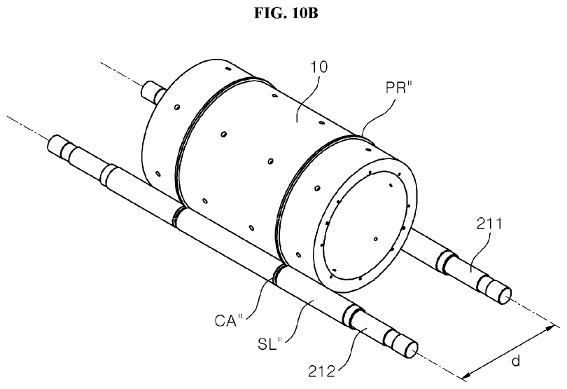

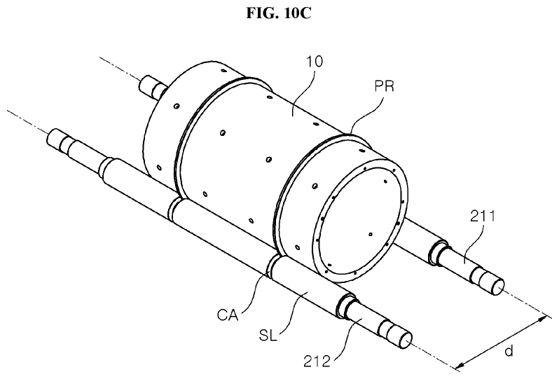

The roller 21 includes a first roller 211 and a second roller 212. The first roller 211 is disposed at one side of the lower portion of the reactor 10, and the second roller 212 is disposed at the other side of the lower portion of the reactor 10. The first roller and the second roller are disposed to be spaced apart from each other at a distance d (see FIGS. 9A to 10C) suitable for supporting the reactor placed thereon. The positions of the first roller and the second roller in this state are also positions that prevent interference between the reactor and the roller during replacement of the reactor. Outer surfaces of the first and second rollers 211 and 212 come in direct contact with an outer surface of the reactor 10. Therefore, when the first and second rollers rotate, the reactor may rotate due to friction between the outer surfaces of the first and second rollers and the outer surface of the reactor.

Here, a concavo-convex structure may be involved to increase a contact area. Protrusions PR may be provided on the outer surface of the reactor 10 along an outer circumferential surface thereof. Grooves CA may be provided on the outer surface of the roller 21 along an outer circumferential surface thereof. The protrusions and the grooves may have structures fitted to each other. For example, the protrusions may be accommodated in the grooves. Such a concavo-convex structure increases the overall friction between the reactor and the roller and facilitates rotation of the reactor 10 caused by the roller 21.

Also, the protrusions and the grooves of such a concavo-convex structure are engaged with each other and prevent back and forth movement of the reactor while the reactor rotates. There is an advantage that the reactor can be freely attached or detached in a direction parallel to the direction of rotation while sliding of the reactor is prevented in the longitudinal direction thereof. Also, by supporting the weight of the mass production type reactor through a relatively large contact area, the acting load is effectively distributed.

Structurally, the first and second rollers support the self-load of the reactor. Thus, the first and second rollers that receive the weight of the reactor may, along with the above-described concavo-convex structure, further facilitate the rotation of the reactor.

The rotating unit 20 further includes a rotating pulley 22 and a motor pulley 23 configured to provide a driving force that rotates the rotating pulley 22. The rotating pulley 22 rotates the roller 21 connected thereto. That is, a rotational force of the motor pulley is provided to the roller through the rotating pulley, and as a result, the reactor rotates.

The rotating pulley 22 includes a first rotating pulley 221 and a second rotating pulley 222. The first rotating pulley 221 has a structure connected to the first roller 211. The second rotating pulley 222 has a structure connected to the second roller 212. The rotating pulley and the roller may be firmly connected to each other so that the driving force from the motor pulley is transmitted to the roller without loss.

The motor pulley 23 receives power and converts the received power into a rotational force and, in this way, causes the rotating pulley 22 to rotate.

In consideration of the structure in which the reactor 10 is placed on the two rollers 211 and 212 and in consideration of the direction in which the two rollers 211 and 212 rotate, it may be advantageous for the rotating pulley 22 and the motor pulley 23 to have triangular arrangement as illustrated in the drawings. This is because, in this way, a single rotation driving shaft (that is, the motor pulley 23) can, with one action, cause the two rollers 211 and 212 and the reactor 10 to rotate.

However, the structures of the rotating pulley and the motor pulley are not limited to those presented in the drawings, and a rotational driving force for rotating the roller may be applied through various other structures. Also, a power transmission method is not limited to the belt driving method illustrated in the drawings, and various other power transmission methods may be used.

As illustrated in the drawings, the roller 21 is substantially positioned inside the chamber unit 30. The rotating pulley 22 and the motor pulley 23 are substantially positioned outside the chamber unit 30. That is, only the roller that comes in direct contact with the rotating reactor is positioned inside the chamber unit.

The chamber unit 30 at least partially accommodates the reactor 10 and the rotating unit 20 and creates a predetermined environment for a deposition reaction of the powder (not illustrated) inside the reactor 10. For example, the predetermined environment may be a vacuum state or a state close to vacuum.

The chamber unit 30 includes an openable/closable lid 31. The lid 31 allows the reactor accommodated in the chamber unit 30 to be replaced with another new reactor when necessary, such as during a cleaning process or replacement of components. The lid 31 may have a sealed structure to allow the predetermined environment to be properly created inside the chamber unit when the chamber unit is closed.

Although the lid 31 is illustrated in the drawings as having a quadrangular plate shape due to the chamber unit 30 having a rectangular parallelepiped shape as a whole, the shape of the lid 31 is not limited thereto.

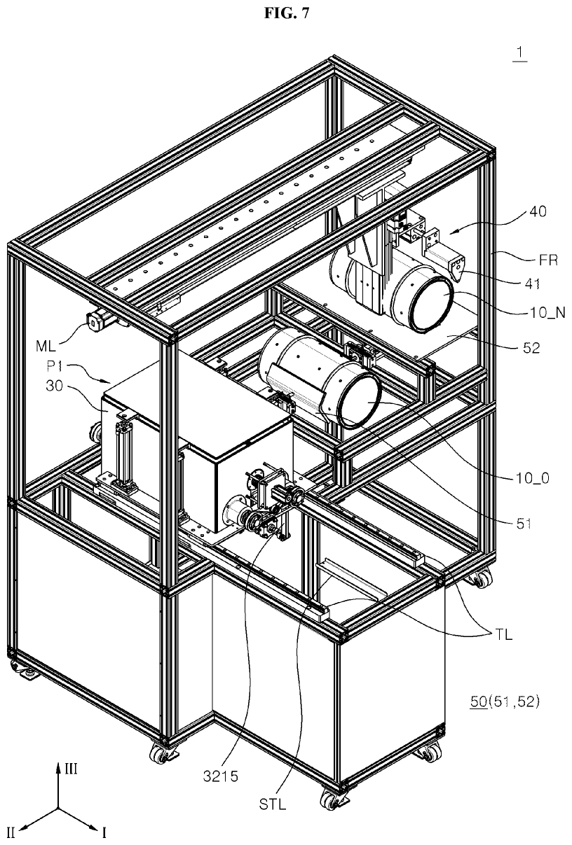

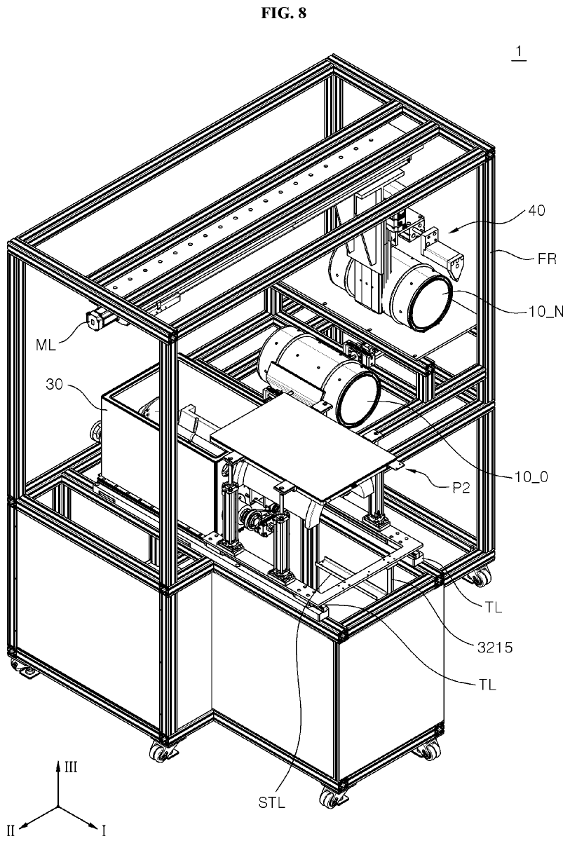

The chamber unit 30 further includes a sliding driving module 32. The sliding driving module 32 slides the lid 31 from a closing position P1 (see FIG. 7) to an opening position P2 (see FIG. 8). A direction of sliding is illustrated as a direction I in the drawings.

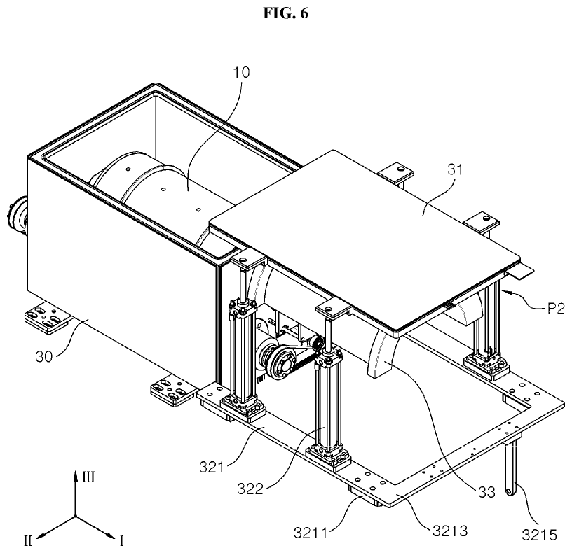

To this end, the sliding driving module 32 includes a moving block 321 and a cylinder 322. The moving block 321 moves along a transfer line TL (see FIG. 7) extending in one direction. The transfer line TL is provided on a frame FR (see FIG. 7). The cylinder 322 is provided on the moving block 321 and pushes the lid 31 upward and opens the lid 31. Thus, during sliding of the lid 31 from the closing position P1 to the opening position P2, the lid 31 is first pushed upward and opened by the cylinder 322 and then slides by the moving block 321, thereby completely (or almost completely) opening an upper surface of the chamber unit. In this way, the lid is opened through two steps. During sliding of the lid 31 from the opening position P2 to the closing position P1, the above-described steps are performed in the reverse order. This will be described below with reference to FIG. 6.

Next, referring to FIGS. 3 to 5 along with FIGS. 1 and 2 which have been described above, the chamber unit 30 further includes a gas supply module 34. According to control of an external controller (not illustrated), the gas supply module 34 supplies a process gas necessary for a process, e.g., a coating source, an oxidizing agent, or a purge gas, to the inside of the reactor 10. As the gas supply module, a gas supply module used in a known deposition module included in Chemical Vapor Deposition (CVD) equipment, Atomic Layer Deposition (ALD) equipment, sputtering equipment, or the like may be applied. In FIG. 5, directions in which a process gas is introduced are indicated by arrows.

The chamber unit 30 further includes a gas damper module 35. The gas damper module 35 includes a cylinder 351 configured to move a close contact portion RC so that the close contact portion RC comes in close contact with the reactor 10 and a bellows 352 configured to keep the chamber unit 30 sealed during the operation of the cylinder 351. For example, the gas damper module 35 maintains the position using a stretchable/compressible element such as a spring and absorbs force input due to vibration or impact. In this way, stability of equipment is enhanced.

In FIG. 5, positions of the gas damper module 35 before and after movement due to the operation of the cylinder 351 are indicated by a solid line and a dotted line, respectively. As the gas damper module 35 moves from the position indicated by the solid line to the position indicated by the dotted line, the close contact portion RC comes in close contact with the reactor 10, and accordingly, the gas damper module 35 can serve to absorb impact as described above.

The chamber unit 30 further includes an upper heater 33 and a lower heater 36. The upper heater 33 is disposed relatively above the reactor 10. The lower heater 36 is disposed relatively below the reactor. The heater 33 or 36 serves to, during coating of the powder in the reactor 10, increase the temperature of the reactor to a temperature necessary for the process. The heater 33 or 36 may be controlled by a separate heater controller (not illustrated).

For effective heating of the reactor, the upper heater 33 and the lower heater 36 may have shapes that can come in contact with the reactor as closely as possible, that is, shapes that substantially correspond to the shape of the reactor. For example, the upper heater or the lower heater may have a semicircular cross-section (see FIG. 6).

Also, the upper heater 33 and the lower heater 36 are provided to be completely physically separated from each other. Therefore, automation of the replacement of the reactor is possible. Due to the characteristic of the rotating unit in which a separate portion fastened to the reactor is not present, during attachment or detachment of the reactor, the reactor may be withdrawn by a robot arm without being decomposed. This will be described below.

The chamber unit 30 further includes a pumping module 37. The pumping module 37 serves to allow the inside of the reactor or the chamber unit to reach a vacuum state and exhaust the process gas provided by the gas supply module 34.

Meanwhile, a mesh filter having a mesh size in a range of 0.5 μm to 3.0 μm is fastened to a front portion of the reactor to allow precursor particles of various sizes to smoothly flow, and a mesh filter having a mesh size in a range of 3.0 μm to 5.0 μm is fastened to a discharge portion in the longitudinal direction of the reactor to prevent a phenomenon in which, during supply of pulses and a purge gas to the inside of the reactor, the powder inside the reactor flows out of the reactor due to pressure of the gas.

FIG. 6 is a view illustrating a state in which the lid 31 of the chamber unit 30 is opened by the sliding driving module 32 according to an embodiment of the present disclosure.

Also, FIGS. 7 and 8 are views illustrating the overall configuration of the powder coating apparatus for describing replacement of the reactor according to an embodiment of present disclosure.

First, referring to FIG. 6 along with FIG. 5 which has been described above, the upper heater 33 may be provided in the shape of a semicircular column. The upper heater 33 and the lid 31 may be coupled to each other through a fastener 331 (see FIG. 5). Therefore, when the lid 31 is moved by the sliding driving module 32, the upper heater 33 is also moved.

Thus, in a state in which the lid 31 is at the opening position P2, an upper portion of the reactor 10 is completely exposed through an upper side of the chamber unit. As will be described below, a robot arm 40 (see FIGS. 7 and 8) allow the reactor to be more easily gripped during the replacement of the reactor. This promotes automation of the replacement of the reactor.

The role of the cylinder 322 becomes clearer. The cylinder 322 serves to sufficiently push the lid 31 upward in consideration of the height of the upper heater coupled in a fixed manner to the lid (first-step opening). During subsequent second-step opening, the cylinder 322 prevents interference by the upper heater.

The moving block 321 includes a plurality of blocks 3211 placed on the transfer line TL (see FIGS. 7 and 8), a body 3213 configured to provide a space for mounting the plurality of blocks 3211, and an auxiliary guide 3215 coupled to the body to aid in alignment while sliding occurs. As the plurality of blocks 3211 in direct contact with the transfer line TL slide along the transfer line TL, the lid 31 connected to the cylinder 322 provided on the body 3213 slides from the closing position P1 to the opening position P2 (second-step opening). Even in this case, the upper heater 33 also moves as in the above-described case.

Next, referring to FIGS. 7 and 8, the powder coating apparatus 1 includes the robot arm 40, which is provided to grip the reactor, and a holder 50.

The robot arm 40 is provided at an upper portion of the frame FR. The holder 50 is substantially provided at an intermediate portion of the frame FR that is lower than the robot arm 40. The robot arm 40 is provided at a position advantageous for gripping the reactor from above the reactor during replacement of the reactor. The holder 50 includes a first holder 51 for a reactor 10_O on which a process has been completed and a second holder 52 for a new reactor 10_N. The first and second holders 51 and 52 are substantially provided between the robot arm 40 and the chamber unit 30, which is a position advantageous for the insertion/withdrawal and mounting of the reactor 10_O or 10_N.

In this way, the robot arm 40 may perform driving to grip the reactor, whose upper portion is completely exposed through the above-described second-step opening, withdraw the gripped reactor vertically upward (that is, in a direction III), and mount the withdrawn reactor on the holder 50.

In consideration of a direction in which the robot arm approaches the reactor to grip the reactor (that is, the direction III), the robot arm may grip the reactor from both sides of the reactor in the longitudinal direction of the reactor as illustrated in the drawings. To this end, the robot arm may include a pair of grippers 41 between which a separation distance is adjusted in the direction I.

The robot arm moving only in one direction (that is, a direction II) to perform replacement of the reactor as illustrated in the drawings is sufficient. As illustrated in the drawings, the chamber unit 30, the first holder 51, and the second holder 52 are placed in the direction II, and thus the robot arm 40 moving only in the direction II is sufficient for performing the insertion/withdrawal and mounting of the reactor 10_O or 10_N. That is, the robot arm 40 moving only in the direction II along a movement line ML provided on the frame FR is sufficient. By optimizing the direction of movement, manufacturing costs are reduced.

In this way, the robot arm may easily transport the reactor to the holder positioned in a direction perpendicular to the chamber unit while the robot arm is installed at the upper portion of the frame, which surrounds the apparatus, and slides.

Meanwhile, a sub-transfer line STL (see FIGS. 7 and 8) for mounting the above-described auxiliary guide 3215 may be further provided on the frame FR. As illustrated in the drawings, the sub-transfer line is provided at a distal end in the direction II from the chamber unit on the frame in order to be advantageous for alignment, and since the sub-transfer line is only involved in mid and later stages of sliding, the sub-transfer line may be formed to be relatively shorter than the transfer line.

FIGS. 9A to 9C are views illustrating various embodiments of the reactor according to an embodiment of the present disclosure in terms of the relationship with the roller.

As illustrated in FIG. 9A, the reactor 10 may include a liner 11 configured to narrow an accommodation space therein configured to accommodate the powder. The liner is a structure whose size is smaller than a diameter of the hollow cylindrical reactor and allows a process to be performed on a small amount of powder relative to the amount of powder charged. That is, the amount of powder charged into the liner may be adjusted from small to large according to a change in the size of the liner, and in this way, both a process for a small amount of powder and a process for mass production may be possible.

The liner 11 may be coupled to an inner circumferential surface of the reactor 10 through a fastener 12. The fastener 12 rotates along with the reactor during rotation of the reactor and prevents the powder from flowing out of the reactor due to the mesh filters at the front and rear sides. A blade 13 configured to accelerate stirring of the charged powder may be provided on an inner circumferential surface of the liner 11. The powder is guided and rotated by the blade, and by a plurality of blades, the powder is mixed within a relatively short time difference, and a process in which the powder is able to react with pulses and a purge gas is enhanced. In the drawings, an example in which a total of six blades are disposed at predetermined intervals along the inner circumferential surface of the liner is illustrated, but the number of blades is not limited thereto.

The inventor of the present disclosure performed a simulation to compare exposure times of powder. From the simulation, based on the point that the exposure time decreases with an increase in the area of powder coming in contact with a wall surface of the reactor, it was found that, in a case in which a process is performed on a small amount of powder in a small-sized reactor, an area of powder coming in contact with a wall surface of the reactor relatively decreases, and an exposure time during which the powder is exposed to a process gas injected into the reactor increases. Therefore, by including the liner configured to narrow the accommodation space inside the reactor, the process efficiency can be improved.

Also, it was found that, during a process on a small amount of powder, assuming that the speed of rotation is the same, the powder freely falls via the blades at a relatively shorter cycle as compared to when the process is performed in a large-sized reactor, and an exposure time during which a surface area of powder particles is exposed to a process gas increases. Based on this, during the process on a small amount of powder, the amount of process gas according to the exposed area may be reduced to improve efficiency of the process.

FIG. 9B relates to an embodiment in which the size of a liner 11′ is increased as compared to the liner 11 in FIG. 9A described above. The fastener 12 and the blades 13 should be provided corresponding to the size of the liner 11′. FIG. 9C shows a reactor in a state in which a liner is not included, unlike in FIG. 9A described above. Even in this case, the blades 13 may be provided, and the blades being provided on the inner circumferential surface of the reactor is sufficient. Meanwhile, it should be noted that the distance d between the two rollers 211 and 212 is maintained constant in FIGS. 9A to 9C described above.

Hereinafter, another embodiment in which the size of the accommodation space inside the reactor is adjusted will be described.

FIGS. 10A to 10C are views illustrating various embodiments of a reactor according to another embodiment of the present disclosure in terms of the relationship with the roller.

As illustrated in FIG. 10A, the size (that is, outer diameter) of the reactor 10 may be designed to be relatively small, and complementarily, the sizes (that is, outer diameters) of the first and second rollers 211 and 212 may be designed to be relatively large. The inner diameter of the liner and the diameters of the first and second rollers define the size of the powder accommodation space. Through compatibility with reactors of various sizes, a small-capacity reactor or a large-capacity reactor may be selectively used, and in this way, both a deposition process for a small amount of powder and a deposition process for a large amount of powder for mass production may be possible.

In FIG. 10A, the outer diameter of the reactor is adjusted to adjust the size of the reactor. However, unlike this, an inner diameter of the reactor 10 may be adjusted as illustrated in FIG. 10B. This is because the accommodation space inside the reactor may be reduced also by decreasing the inner diameter. Even in this case, the sizes of the first and second rollers 211 and 212 may be adjusted complementarily. For comparison with FIGS. 10A and 10B, FIG. 10C shows the reactor and the rollers which are in a default state in which the sizes thereof are not adjusted. Meanwhile, it should be noted that the distance d between the two rollers 211 and 212 is maintained constant in FIGS. 10A to 10C, as well as FIGS. 9A to 9C described above. Since the rollers are to be firmly connected with the rotating pulley described above, maintaining a constant distance between the rollers allows design of reactors and rollers of various sizes without changing the design of the chamber unit itself. Also, in adjusting the size (e.g., outer diameter) of the roller, to allow such adjustment to be possible without a change in an axis of rotation thereof, a sleeve SL may be provided on the roller. The sleeve forms a diameter adaptive to the diameter of the reactor so that the first roller 211 and the second roller 212 are able to come in direct contact with the reactor regardless of the diameter of the reactor.

Meanwhile, it should be noted that, as the sizes of the reactors and the rollers are adjusted, protrusions PR′, PR″, and PR provided on the reactors and grooves CA′, CA″, and CA provided on the rollers are also adjusted adaptively.

The above-described embodiments of the present disclosure provide a technology in which, through a rotating unit having a higher degree of freedom in terms of fastening a reactor as compared to the related art, full automation of a robot arm that allows the reactor to be freely attached to or detached from a chamber unit is possible and, through a liner inside the reactor, coating of both a small amount of powder and a large amount of powder is possible.

Also, due to a structure in which a reactor can be freely mounted using a robot arm instead of being fastened by a structure such as a separate gear fastening structure, the apparatus of the present disclosure is compatible with reactors of various sizes and lengths.

Also, using a robot arm, a reactor on which a process has been completed is transferred to a holder to finish a task, and a reactor prepared on an extra holder is transferred to a chamber to enable a continuous process.

In this way, by shortening a moving distance of the robot arm, efficiency of full automation can be increased, and yield of the overall process can be improved.

Also, by changing the sizes of a liner, a roller, and a key according to an embodiment of the present disclosure, the amount of charged powder may be freely adjusted from small to large, and accordingly, efficient process optimization is possible.

The reactor according to the above-described embodiments of the present disclosure may be applied to fields such as thin film deposition, atomic layer deposition, and powder coating and may, of course, be applied to high-performance thin film coating equipment, large-capacity powder coating equipment, and the like.

According to the present disclosure, since a fastening portion is not present in a powder coating apparatus itself, full automation in which a mass production reactor is separated from a chamber unit and transferred to a holder by a robot arm is facilitated. Thus, there is an advantage that the time until a subsequent process is reduced and product yield is increased.

Also, according to the present disclosure, it is possible to provide an apparatus that is compatible with reactors of various sizes and allows structural changes so that a maximum of 10 kg of powder can be charged therein and coated during use of mass production equipment for deposition on a small amount of powder and mass production equipment for deposition on a large amount of powder.

Also, due to a rotating unit using a pulley in which a separate fastening portion such as a gear is not present, the present disclosure has a structure in which a reactor rotates and causes a large amount of powder charged therein to be stirred, and the present disclosure has advantages that reactors of various sizes can be fastened by adjusting sizes of a roller of the rotating unit and protrusions and grooves that serve as keys, and deposition on powder of various amounts, from small to large, is possible by installing structures and liners of various sizes and shapes inside the reactor.

In addition, according to the present disclosure, it is possible to provide a mass production type powder coating apparatus having a full automation characteristic in which, due to a rotating unit using a pulley without a gear when opening or closing a lid of a chamber before or after a process, a reactor has freedom in fastening and can be freely transferred using a robot arm.

The present disclosure has been described above using certain details, such as specific elements, and some embodiments and drawings, but these are only provided to assist in better understanding of the present disclosure, and the present disclosure is not limited by the embodiments described above. Various modifications and changes may be made to the above by those of ordinary skill in the art to which the present disclosure pertains. Therefore, the spirit of the present disclosure should not be defined as being limited by the embodiments described herein, and not only the claims below but also their equivalents or anything with their equivalent variants belong to the scope of the spirit of the present disclosure.

What is claimed is:

1. A powder coating apparatus comprising:
a reactor configured to rotate and improve reactivity of powder accommodated therein;
a rotating unit including a roller which is positioned at a lower portion of the reactor and configured to rotate while in direct contact with the reactor and cause the reactor to rotate; and
a chamber unit configured to at least partially accommodate the reactor and the rotating unit and create a predetermined environment for a deposition reaction of the powder inside the reactor,
wherein the chamber unit includes an openable/closable lid to allow the reactor to be replaced with a new reactor.

2. The powder coating apparatus of claim 1, wherein the chamber unit further includes a sliding driving module configured to slide the lid from a closing position to an opening position.

3. The powder coating apparatus of claim 2, wherein the sliding driving module includes:
a moving block configured to move along a transfer line extending in one direction; and
a cylinder provided on the moving block and configured to push the lid upward and open the lid.

4. The powder coating apparatus of claim 3, wherein the moving block includes a plurality of blocks placed on the transfer line, a body configured to provide a space for mounting the plurality of blocks, and an auxiliary guide coupled to the body to aid in alignment while sliding occurs.

5. The powder coating apparatus of claim 3, wherein the chamber unit further includes an upper heater configured to heat the reactor placed therein from above the reactor,
wherein the upper heater is coupled to the lid and pushed upward along with the lid while the lid is pushed upward by the cylinder, and in a state in which the lid is at the opening position, an upper portion of the reactor is completely exposed through an upper side of the chamber unit.

6. The powder coating apparatus of claim 5, wherein the upper heater and the lid are coupled to each other through a fastener.

7. The powder coating apparatus of claim 5, further comprising:
a robot arm provided to grip the reactor; and
a holder,
wherein the robot arm performs driving to grip the exposed reactor, withdraw the gripped reactor vertically upward, and mount the withdrawn reactor on the holder.

8. The powder coating apparatus of claim 1, wherein:
the roller includes a first roller disposed at one side of the lower portion of the reactor and a second roller disposed at the other side of the lower portion of the reactor; and
the first roller and the second roller are disposed at positions not interfering with replacement of the reactor with a new reactor.

9. The powder coating apparatus of claim 8, wherein the reactor includes a liner configured to narrow an accommodation space therein configured to accommodate the powder.

10. The powder coating apparatus of claim 9, wherein the first roller and the second roller have a sleeve configured to form a diameter adaptive to a diameter of the reactor so that the first roller and the second roller are able to come in direct contact with the reactor regardless of the diameter of the reactor.

11. The powder coating apparatus of claim 8, wherein the first and second rollers and the reactor have therebetween a structure in which concave and convex portions come in contact.

12. The powder coating apparatus of claim 1, wherein the chamber unit further includes:
a gas supply module configured to supply a process gas to one side of the reactor; and
a gas damper module configured to come in close contact with the other side of the reactor to serve as an impact absorber.

13. A powder coating apparatus comprising:
a reactor configured to rotate and improve reactivity of powder accommodated therein;
a rotating unit positioned at a lower portion of the reactor and configured to rotate while in direct contact with the reactor and cause the reactor to rotate; and
a chamber unit configured to at least partially accommodate the reactor and the rotating unit and create a predetermined environment for a deposition reaction of the powder inside the reactor,
wherein the chamber unit further includes a lid which is provided to be slidable in a first direction and configured to cause an upper portion of the reactor disposed therein to be exposed to an outside and a robot arm which is provided to be slidable in a second direction and configured to withdraw the exposed reactor in a third direction.
